(19) United States
(12) Patent Application Publication
(10) Pub. No.: US 2024/0304597 A1
(43) Pub. Date: Sep. 12, 2024

(54) OPTICAL SENSOR AND DISPLAY APPARATUS

(71) Applicant: BOE Technology Group Co., Ltd., Beijing (CN)

(72) Inventors: Xiaoquan HAI, Beijing (CN); Yingzi WANG, Beijing (CN); Xue DONG, Beijing (CN); Guangcai YUAN, Beijing (CN); Chunfang ZHANG, Beijing (CN); Xuan LIANG, Beijing (CN)

(21) Appl. No.: 18/666,589

(22) Filed: May 16, 2024

Related U.S. Application Data
(63) Continuation of application No. PCT/CN2022/114676, filed on Aug. 25, 2022.

(51) Int. Cl. H01L 25/04; G06V 40/13; H01L 25/16; H01L 31/0232

(52) U.S. Cl. CPC H01L 25/042; G06V 40/1306; G06V 40/1318; H01L 25/167; H01L 31/02327

(57) ABSTRACT

An optical sensor and a display apparatus. The optical sensor includes: a base substrate (1); a detection circuit (2) on the base substrate (1); a plurality of photosensitive devices (3) on a side of the detection circuit (2) facing away from the base substrate (1); a plurality of light converged elements (4) on a side of the photosensitive devices (3) facing away from the base substrate (1); where an orthographic projection of one light converged element (4) on the base substrate (1) covers orthographic projections of at least two photosensitive devices (3) on the base substrate (1); and a light constrained structure (5) between the photosensitive devices (3) and the light converged elements (4).

### CROSS-REFERENCE TO RELATED APPLICATIONS

The present disclosure is a continuation of International Application No. PCT/CN2022/114676, filed on Aug. 25, 2022, all of which is hereby incorporated by reference in its entirety.

### TECHNICAL FIELD

The present disclosure relates to the field of sensing technology, and in particular, relates to an optical sensor and a display apparatus.

### BACKGROUND

Due to the increasing miniaturization of handheld electronic products in the future, there is an urgent need for handheld electronic products to develop towards the thinner thickness, the smaller volume, and the higher integration level. At present, resin materials are used to directly integrate multi-layer diaphragms and micro-lenses on the surface of sensors, which can effectively reduce the three pain points of collimation film adhesion: large angle crosstalk, oblique/molar stripes on the film material, and reliability being not good (NG), thereby improving the accuracy of the identified fingerprint information in the optical fingerprint recognition process.

### SUMMARY

Embodiments of the present disclosure provide an optical sensor and a display apparatus, and the specific solutions are as follows.

Embodiments of the present disclosure provide an optical sensor, including:
a base substrate;
a detection circuit on the base substrate;
a plurality of photosensitive devices, arranged on a side of the detection circuit facing away from the base substrate;
a plurality of light converged elements, arranged on a side of the plurality of photosensitive devices facing away from the base substrate; where an orthographic projection of one of the plurality of light converged elements on the base substrate covers orthographic projections of at least two of the plurality of photosensitive devices on the base substrate; and
a light constrained structure between the plurality of photosensitive devices and the plurality of light converged elements; where the light constrained structure includes a plurality of optical channels corresponding to the plurality of photosensitive devices one by one; each of the plurality of optical channels is obliquely arranged, and adjacent two optical channels are symmetrically arranged about a central axis of one light converged element; and each of the plurality of optical channels is configured to allow incident light within an incidence angle of (ϕ−θ, ϕ+Θ) to be directed onto the photosensitive device, where, ϕ is an angle between a central axis of the optical channel and the central axis of the light converged element.

In a possible implementation, in the above-mentioned optical sensor provided by embodiments of the present disclosure, the orthographic projection of the light converged element on the base substrate covers orthographic projections of k² photosensitive devices on the base substrate; and k is a positive even number.

In a possible implementation, in the above-mentioned optical sensor provided by embodiments of the present disclosure, a value of ϕ ranges from 42° to 70°; and a value of θ ranges from 0.5° to 12°.

In a possible implementation, in the above-mentioned optical sensor provided by embodiments of the present disclosure, the light constrained structure includes at least two diaphragm layers arranged in stacked; each of the at least two diaphragm layers has a plurality of openings which are in one-to-one correspondence with the plurality of photosensitive devices; and at least two stacked openings above each of the plurality of photosensitive devices are arranged in a staggered manner to form an optical channel corresponding to the photosensitive device.

In a possible implementation, in the above-mentioned optical sensor provided by embodiments of the present disclosure, the light constrained structure includes at least two diaphragm layers arranged in stacked; the diaphragm layer closest to the plurality of light converged elements has a plurality of first openings; the diaphragm layer close to the plurality of photosensitive devices has a plurality of second openings which are in one-to-one correspondence with the plurality of photosensitive devices; an orthographic projection of one of the plurality of first openings on the base substrate covers orthographic projections of at least two of the plurality of second openings on the base substrate; a connecting line between a center point of the first opening and a center point of the second opening is obliquely arranged; and the first opening and the second opening stacked above each of the plurality of photosensitive devices form the optical channel.

In a possible implementation, in the above-mentioned optical sensor provided by embodiments of the present disclosure, the orthographic projection of the first opening on the base substrate covers orthographic projections of k² second openings on the base substrate, and k is a positive even number.

In a possible implementation, in the above-mentioned optical sensor provided by embodiments of the present disclosure, each of the at least two diaphragm layers includes a transparent layer and a light shielding layer on a surface of the transparent layer facing away from the light converged element, and the light shielding layer is provided with the plurality of openings.

In a possible implementation, in the above-mentioned optical sensor provided by embodiments of the present disclosure, the optical sensor further includes a light filter film layer. The light filter film layer is multiplexed as a transparent layer of any one of the diaphragm layers; or the light filter film layer is inside the transparent layer of any one of the diaphragm layers, and an orthographic projection of the light filter film layer on the base substrate at least covers an orthographic projection of the opening on the base substrate.

In a possible implementation, in the above-mentioned optical sensor provided by embodiments of the present disclosure, a shape of the opening is a triangle, a square or a circle.

In a possible implementation, in the above-mentioned optical sensor provided by embodiments of the present disclosure, the optical sensor satisfies the following relationship:
D=2P−t; where, t is a distance between two adjacent light converged elements, D is a clear aperture of the light converged element, and P is a size of the photosensitive device;
H1+H2=(D\hat{ }2+4hs\hat{ }2)*(nt/(ns−1))−nt*hs/ns; where, nt is a refractive index of the transparent layer, ns is a refractive index of the light converged element, hs is an arch height of the light converged element, and H1 and H2 are thicknesses of transparent layers respectively;
d1=(D\ddot{ } 2+4hs\hat{ }2)*(nt/(ns−1))*(cot(ϕ+θ)− cot(ϕ−θ)); where d1 is a size of an opening of the light shielding layer close to the photosensitive device;
d2=H2*D/((D\hat{ }2+4hs\hat{ }2)*(nt/(ns−1))−nt*hs/ns); where d2 is a size of an opening of the light shielding layer far away from the photosensitive device;
d1y=H1+H2, and d1x=d1y*tan ϕ; where, d1y is an offset in a direction Y of a center of the opening in the light shielding layer close to the photosensitive device relative to a center of the light converged element, and d1x is an offset in a direction X of the center of the opening in the light shielding layer close to the photosensitive device relative to the center of the light converged element; and
d2y=H1, and d2x=d2y*tan ϕ; where, d2y is an offset in the direction Y of a center of the opening in the light shielding layer far away from the photosensitive device relative to the center of the light converged element, and d2x is an offset in the direction X of the center of the opening in the light shielding layer far away from the photosensitive device relative to the center of the light converged element.

In a possible implementation, in the above-mentioned optical sensor provided by embodiments of the present disclosure, the light converged element includes at least one of: a lens, a Fresnel zone plate, a grating, or a Fresnel lens.

In a possible implementation, in the above-mentioned optical sensor provided by embodiments of the present disclosure, the optical sensor further includes a light converged layer arranged on a side of the light constrained structure facing away from the base substrate;

and the light converged layer includes a plurality of through-holes, and the through-hole constitutes the light converged element.

In a possible implementation, in the above-mentioned optical sensor provided by embodiments of the present disclosure, the optical sensor further includes: a first planarization layer arranged between the detection circuit and the photosensitive device, and a first passivation layer arranged between the first planarization layer and the photosensitive device; and the photosensitive device includes a bottom electrode, a photosensitive layer and a top electrode arranged in stacked on the first passivation layer; the bottom electrode is electrically connected with the detection circuit by a first via-hole penetrating through the first passivation layer and the first planarization layer; and an orthographic projection of the photosensitive layer on the base substrate does not overlap with an orthographic projection of the first via-hole on the base substrate.

In a possible implementation, in the above-mentioned optical sensor provided by embodiments of the present disclosure, the photosensitive device includes a bottom electrode, a photosensitive layer and a top electrode arranged in stacked; and the bottom electrode is arranged in the same layer as source and drain electrodes of the detection circuit, and the bottom electrode and the drain electrode of the detection circuit are an integrated structure.

In a possible implementation, in the above-mentioned optical sensor provided by embodiments of the present disclosure, the detection circuit includes a first transistor, a second transistor, and a third transistor; a gate electrode of the first transistor is electrically connected with a first control line, a first electrode of the first transistor is electrically connected with a signal reading end, and a second electrode of the first transistor is electrically connected with a first electrode of the second transistor; a second electrode of the second transistor is electrically connected with a first power supply terminal, and a gate electrode of the second transistor and a first electrode of the third transistor are both electrically connected with the photosensitive device; and a second electrode of the third transistor is electrically connected with a reset signal line, and a gate electrode of the third transistor is electrically connected with a second control line. The first transistor, the second transistor and the third transistor are all double-gate structures.

In a possible implementation, in the above-mentioned optical sensor provided by embodiments of the present disclosure, a width-to-length ratio of the second transistor is greater than a width-to-length ratio of the third transistor, and the width-to-length ratio of the third transistor is greater than or equal to a width-to-length ratio of the first transistor.

In a possible implementation, in the above-mentioned optical sensor provided by embodiments of the present disclosure, the optical sensor further includes: a cover layer arranged between the photosensitive device and the light constrained structure; a second planarization layer arranged between the cover layer and the light constrained structure; a second passivation layer arranged between the second planarization layer and the light constrained structure; a first transparent electrode layer arranged between the second passivation layer and the light constrained structure; a barrier layer arranged between the first transparent electrode layer and the light constrained structure; and a second transparent electrode layer arranged between the barrier layer and the light constrained structure. The first transparent electrode layer is electrically connected with the top electrode of the photosensitive device by a second via-hole penetrating through the second passivation layer, the second planarization layer and the cover layer.

Accordingly, embodiments of the present disclosure also provide a display apparatus including a display panel and the optical sensor according to any one of claims 1 to 17; and the optical sensor is arranged on a back surface of the display panel.

In a possible implementation, in the above-mentioned display apparatus provided by embodiments of the present disclosure, the display apparatus further includes: a third planarization layer arranged between the light converged element and the display panel, and an optical adhesive layer arranged between the third planarization layer and the display panel.

### BRIEF DESCRIPTION OF FIGURES

FIG. 1 is a schematic diagram of the structure of an optical sensor provided by an embodiment of the present disclosure.

FIG. 2 is another schematic diagram of the structure of an optical sensor provided by an embodiment of the present disclosure.

FIG. 3 is a planar schematic diagram of partial film layers in the structure shown in FIG. 1.

FIG. 4 is another planar schematic diagram of partial film layers in the structure shown in FIG. 1.

FIG. 5 is another schematic diagram of the structure of an optical sensor provided by an embodiment of the present disclosure.

FIG. 6 is another schematic diagram of the structure of an optical sensor provided by an embodiment of the present disclosure.

FIG. 7 is another schematic diagram of the structure of an optical sensor provided by an embodiment of the present disclosure.

FIG. 8 is a planar schematic diagram of partial film layers in the structure shown in FIG. 7.

FIG. 9 is another schematic diagram of the structure of an optical sensor provided by an embodiment of the present disclosure.

FIG. 10 is another schematic diagram of the structure of an optical sensor provided by an embodiment of the present disclosure.

FIG. 11 is a transmittance spectra diagram of a light filter film layer in the visible light range.

FIG. 12A is another schematic diagram of the structure of an optical sensor provided by an embodiment of the present disclosure.

FIG. 12B is a schematic diagram of the structure of Fresnel zone plate.

FIG. 13A is another schematic diagram of the structure of an optical sensor provided by an embodiment of the present disclosure.

FIG. 13B is a planar schematic diagram of a grating.

FIG. 13C is a cross-section schematic diagram of a grating.

FIG. 14A is another schematic diagram of the structure of an optical sensor provided by an embodiment of the present disclosure.

FIG. 14B is a planar schematic diagram of Fresnel lens.

FIG. 15A is another schematic diagram of the structure of an optical sensor provided by an embodiment of the present disclosure.

FIG. 15B is a planar schematic diagram of partial film layers in FIG. 15A.

FIG. 16 is another schematic diagram of the structure of an optical sensor provided by an embodiment of the present disclosure.

FIG. 17 is a schematic diagram of an equivalent circuit of the detection circuit.

FIG. 18 is a layout diagram of the detection circuit.

FIG. 19A to FIG. 19P are planar schematic diagrams of partial film layers in the structure shown in FIG. 5.

FIG. 20 is a schematic diagram of a structure of a display apparatus provided by an embodiment of the present disclosure.

### DETAILED DESCRIPTION

In order to make the purpose, technical solutions and advantages of embodiments of the present disclosure more clear, the technical solutions of embodiments of the present disclosure will be clearly and completely described below in conjunction with the drawings of embodiments of the present disclosure. Obviously, the described embodiments are some, but not all, of embodiments of the present disclosure. And the embodiments and features in embodiments of the present disclosure may be combined with each other without conflict. Based on the described embodiments of the present disclosure, all other embodiments obtained by those of ordinary skill in the art without creative efforts fall within the scope of the present disclosure.

Unless otherwise defined, technical terms or scientific terms used in this disclosure shall have the usual meaning understood by a person with ordinary skill in the art to which this disclosure belongs. Words such as “including” or “comprising” mean that the component or object that appears before the word includes components or objects listed after the word and their equivalents, without excluding other components or objects. Words such as “connected” or “connecting” are not limited to physical or mechanical connections, but may include electrical connections, whether direct or indirect. Words such as “inside”, “outside”, “up”, “down” are only used to express relative positional relationships. When the absolute position of the described object changes, the relative positional relationship may also change accordingly.

It should be noted that the sizes and shapes of the figures in the drawings do not reflect true proportions and are only intended to illustrate the present disclosure. And the same or similar reference numbers throughout represent the same or similar elements or elements with the same or similar functions.

In the existing optical sensor structure, the ambient light cannot be filtered strictly and completely, and there is still a certain gap between the actual spectrum and the ideal spectrum, resulting in a low signal to noise ratio (SNR) of fingerprints, that is, the fingerprint performance is poor. In addition, the small-sized (D<100 nm) micro-lens is mainly applicable to the silicon-based CMOS image sensor (CIS) manufacturing process. For the glass process of the small-sized (D<100 nm) micro-lens, the process is difficult, the cost is increased, and large-scale production is impossible. However, large-sized (D≥100 nm) micro-lenses are relatively mature in the industry and can meet the needs of glass base. Therefore, how to use large-size micro-lens to realize the integration scheme of optical sensors, when ensuring that the high resolution (PPI) of the optical sensor devices does not change, is a technical problem that needs to be solved urgently.

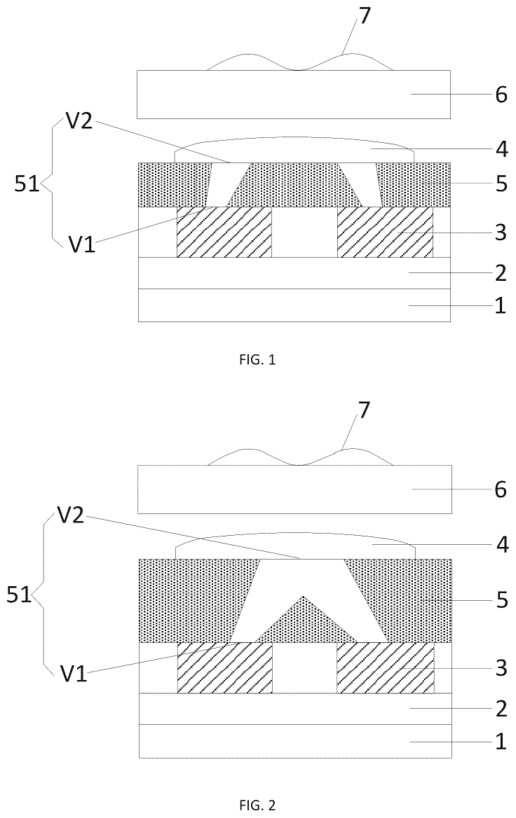

In view of this, embodiments of the present disclosure provide an optical sensor, as shown in FIGS. 1 and 2, including:
a base substrate 1;
a detection circuit 2 on the base substrate 1;
a plurality of photosensitive devices 3, arranged on a side of the detection circuit 2 facing away from the base substrate 1;
a plurality of light converged elements 4, arranged on a side of the plurality of photosensitive devices 3 facing away from the base substrate 1; where an orthographic projection of one of the plurality of light converged elements 4 on the base substrate 1 covers orthographic projections of at least two of the plurality of photosensitive devices 3 on the base substrate 1; and
a light constrained structure 5, arranged between the plurality of photosensitive devices 3 and the plurality of light converged elements 4; where the light constrained structure 5 includes a plurality of optical channels 51 corresponding to the plurality of photosensitive devices 3 one by one; each of the plurality of optical channels 51 is obliquely arranged, and adjacent two optical channels 51 are symmetrically arranged about a central axis of one light converged element 4; and each of the plurality of optical channels 51 is configured to allow incident light within an incidence angle of (ϕ−θ, ϕ+θ) to be directed onto the photosensitive device 3, where, ϕ is an angle between a central axis of the optical channel 51 and the central axis of the light converged element 4.

In the above optical sensor provided by embodiments of the present disclosure, during fingerprint recognition, when the finger touches the screen of display panel 6, the light constrained structure 5 can filter out light reflected from the fingerprint 7 with the small angle (ϕ−θ, ϕ+θ), which is nearly collimated, allowing it to reach the photosensitive devices 3 below. The photosensitive devices 3 can detect the intensity of the light. The energy of the downward diffuse reflection light from the valley and ridge of the fingerprint is different, and the light intensity detected by the photosensitive device 3 array is different, so that the fingerprint information can be obtained. In addition, by arranging the oblique optical channels 51, and by adjusting the design of the optimal matching relationship between the parameters in the light constrained structure 5 and the size and position of the photosensitive devices 3 below, the light constrained structure 5 can control its light receiving angle within the range of (ϕ−θ, ϕ+θ), allow only part of the light to enter the photosensitive devices 3, and block the external strong ambient light within the angle range of (0˜ϕ−θ, ϕ+θ˜90°), to solve the problem of the impact of external strong ambient light on the optical sensing performance, and further improve the recognition performance. In addition, by setting a light converged element 4 to cover at least two photosensitive devices 3, that is, the size of the light converged element 4 is larger than the size of the photosensitive device 3, it is possible to make a large-sized light converged element 4, reducing the process difficulty. Moreover, when the photosensitive devices 3 are made in a large area array, since two adjacent optical channels 51 are symmetrically arranged about the central axis of the light converged element 4, the two adjacent light constrained structures 5 can image the fingerprint twice. On the one hand, the collected images can complement each other to improve the accuracy of fingerprint recognition, and on the other hand, the number of photosensitive devices 3 can be reduced on the basis of achieving the same resolution, while also reducing the space occupied by optical sensors in the electronic device. Therefore, embodiments of the present disclosure can realize the fingerprint collimation scheme design by using multiple photosensitive devices 3 to share the same light converged element 4 without reducing the resolution.

Specifically, the base substrate can be a rigid substrate or a flexible substrate. The material of the rigid substrate can be transparent glass, transparent plastic, etc. The material of the flexible substrate can be polyimide (PI), polyethersulfone (PES), polycarbonate (PC), polyethylene terephthalate (PET), polyethylene naphthalate (PEN), polyaryl compounds (PAR), glass fiber reinforced plastics (FRP) and other polymer materials.

Specifically, the photosensitive device can be a PIN type photodiode.

In some embodiments, in the above optical sensor provided by embodiments of the present disclosure, a value of ϕ ranges from 42° to 70°; and a value of θ ranges from 0.5° to 12°.

In some embodiments of the present disclosure, as shown in FIG. 1 and FIG. 2, when defining the central axis of the optical channel 51, the optical channel 51 includes a light incident hole V2 close to the light converged element 4 and a light exiting hole V1 close to the photosensitive device 3. The central axis of the optical channel 51 is defined as the connecting line between the center of the light incident hole V2 and the center of the light exiting hole V1. In embodiments of the application, the shapes of the light incident hole V2 and the light exiting hole V1 are not limited, and can be triangular, square, circular, etc.

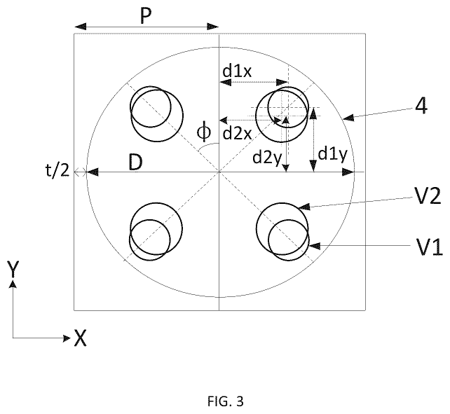

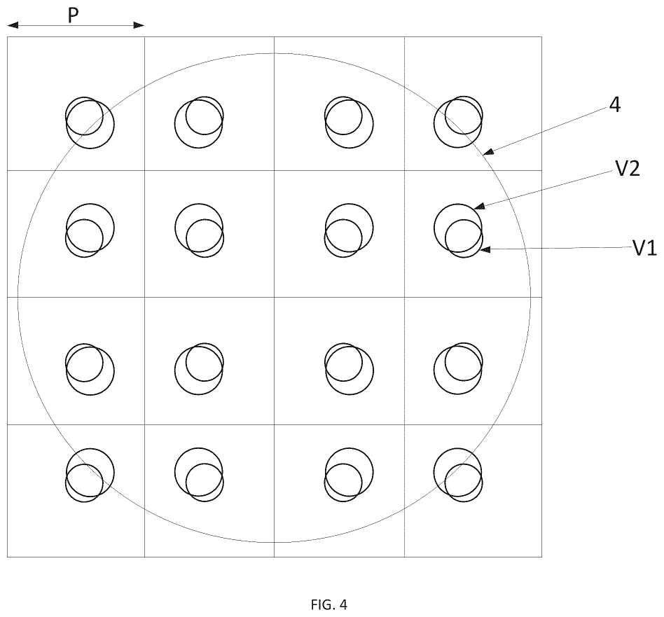

In some embodiments, when the light-sensitive devices are made in a large-area array, in order to ensure that two adjacent optical channels can image the fingerprint twice and the collected images can complement each other to improve the accuracy of fingerprint recognition, in the above optical sensor provided by embodiments of the present disclosure, the orthographic projection of one of the plurality of light converged elements on the base substrate covers orthographic projections of k² photosensitive devices on the base substrate; where k is a positive even number. For example, taking the structure shown in FIG. 1 as an example, as shown in FIG. 3 which is a planar schematic diagram of partial film layers in the structure shown in FIG. 1, one light converged element 4 can correspondingly cover four photosensitive devices 3 (each photosensitive device 3 and the detection circuit 2 correspond to one sub-pixel P, that is, one light converged element 4 can correspondingly cover four sub-pixels P). As shown in FIG. 4 which is another planar schematic diagram of partial film layers in the structure shown in FIG. 1, one light converged element 4 can correspondingly cover sixteen photosensitive devices 3 (sub-pixels P), and so on.

The following embodiments provided in the disclosure are all described with the example of one light converged element 4 covering four sub pixels P.

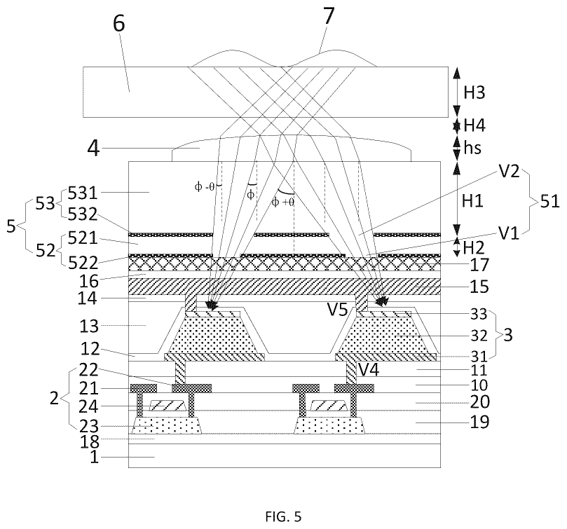

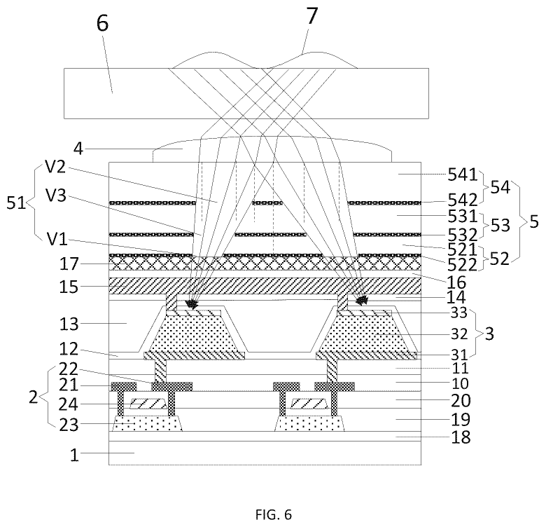

In some embodiments, in the above optical sensor provided by embodiments of the present disclosure, as shown in FIG. 5 and FIG. 6, which are two specific structural schematic diagrams corresponding to FIG. 1, the light constrained structure 5 can include at least two diaphragm layers arranged in stacked. Specifically, in order to ensure that the light reflected from the fingerprint is nearly collimated and incident on the photosensitive devices 3, as shown in FIG. 5, the light constrained structure 5 includes two diaphragm layers (52 and 53) arranged in stacked. The diaphragm layer 52 is provided with a plurality of openings (i.e. light exiting holes V1) which are in one-to-one correspondence with the photosensitive device 3, and the diaphragm layer 53 is provided with a plurality of openings (i.e. light incident holes V2) which are in one-to-one correspondence with the photosensitive device 3. The two stacked openings (V2 and V1) above each of the plurality of photosensitive devices 3 are arranged in a staggered manner to form an optical channel 51 corresponding to the photosensitive device 3. In order to ensure the best fingerprint recognition effect, the diaphragm layers can be three or more layers. For example, as shown in FIG. 6, the light constrained structure 5 includes three layers of diaphragm layers (52, 53 and 54) arranged in stacked. The diaphragm layer 52 is provided with a plurality of openings (i.e., the light exiting holes V1) which are in one-to-one correspondence with the photosensitive devices 3, the diaphragm layer 53 is provided with a plurality of openings (i.e., middle holes V3) which are in one-to-one correspondence with the photosensitive devices 3, the diaphragm layer 54 is provided with a plurality of openings (i.e., the light incident holes V2) which are in one-to-one correspondence with the photosensitive devices 3, and three stacked openings (V2, V3 and V1) above each of the plurality of photosensitive devices 3 are arranged in a staggered manner to form an optical channel 51 corresponding to the photosensitive device 3.

Specifically, as shown in FIGS. 5 and 6, the centers of the light exiting hole V1 and the light incident hole V2 is in a straight line with the center of the light converged element 4, and the angle between the straight line and the central axis of the light converged element 4 is. In addition, the center of the light converged element 4 coincides with the center of the basic unit composed of four sub pixels.

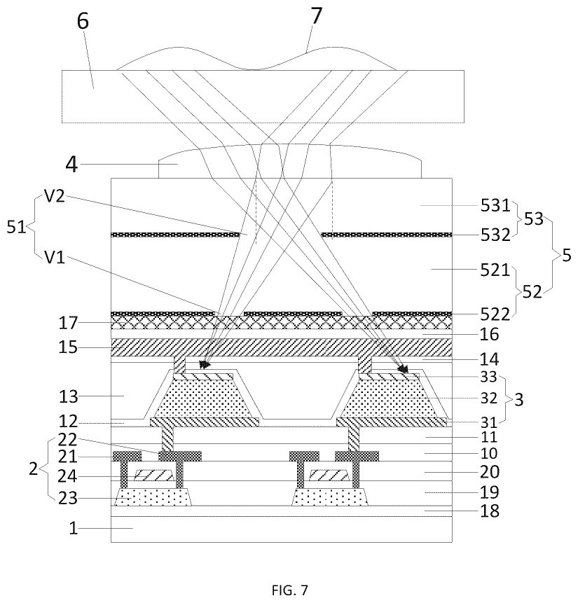

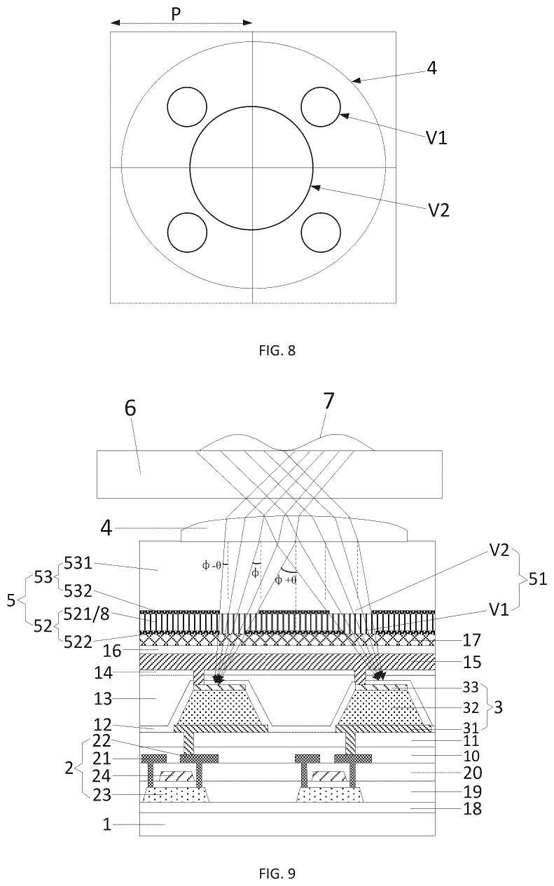

In some embodiments, in the above optical sensor provided by embodiments of the present disclosure, as shown in FIG. 7, which is a specific structural schematic diagram corresponding to FIG. 1, the light constrained structure 5 includes at least two diaphragm layers arranged in stacked (52 and 53 respectively, taking the two diaphragm layers as an example). The diaphragm layer 53 closest to the light converged elements 4 has a plurality of first openings (i.e., the light incident holes V2), and the diaphragm layer 52 close to the photosensitive devices 3 has a plurality of second openings (i.e. the light exiting holes V1) which are in one-to-one correspondence with the photosensitive devices 3. An orthographic projection of one first opening (the light incident hole V2) on the base substrate 1 covers orthographic projections of at least two second openings (the light exiting holes V1) on the base substrate 1; a connecting line between a center point of the first opening (the light incident hole V2) and a center point of the second opening (the light exiting hole V1) is obliquely arranged; and the first opening (the light incident hole V2) and the second opening (the light exiting hole V1) stacked above each of the plurality of photosensitive devices 3 form the optical channel 51. As shown in FIG. 8, which is the planar schematic diagram of partial film layers in the structure shown in FIG. 7, one light converged element 4 corresponds to one light incident hole V2 and four light exiting holes V1, and each light exiting hole V1 corresponds to one sub-pixel P below, which also enables the light constrained structure 5 to control the light receiving angle of the light received by the photosensitive device 3 within the range of (ϕ−θ, ϕ+θ).

In some embodiments, in the above optical sensor provided by embodiments of the present disclosure, as shown in FIG. 7, an orthographic projection of one first opening (the light incident hole V2) on the base substrate 1 can cover orthographic projections of k² second openings (the light exiting holes V1) on the substrate 1, where k is a positive even number. For example, as shown in FIG. 8, one first opening (the light incident hole V2) can correspondingly cover four sub pixels P. Of course, one first opening (the light incident hole V2) can also cover sixteen sub pixels P, and so on.

In some embodiments, in the above optical sensor provided by embodiments of the present disclosure, as shown in FIGS. 5 to 7, the diaphragm layer 52 includes a transparent layer 521 and a light shielding layer 522 arranged on a surface of the transparent layer 521 facing away from the light converged elements 4, and the light shielding layer 522 is provided with the openings (the light exiting holes V1). As shown in FIGS. 5 and 7, the diaphragm layer 53 includes a transparent layer 531 and a light shielding layer 532 arranged on a surface of the transparent layer 531 facing away from the light converged elements 4, and the light shielding layer 532 is provided with the openings (the light incident holes V2). As shown in FIG. 6, the diaphragm layer 53 includes a transparent layer 531 and a light shielding layer 532 arranged on a surface of the transparent layer 531 facing away from the light converged elements 4, and the light shielding layer 532 is provided with the openings (the middle holes V3). As shown in FIG. 6, the diaphragm layer 54 includes a transparent layer 541 and a light shielding layer 542 arranged on a surface of the transparent layer 541 facing away from the light converged elements 4, and the light shielding layer 542 is provided with the openings (the light incident holes V2).

Optionally, a material of the light shielding layer can be a metal material with low transmittance, such as molybdenum, or a black resin, such as black matrix (BM). A material of the transparent layer can be resin, silicon on glass (SOG) and Benzocyclobutene (BCB), etc.

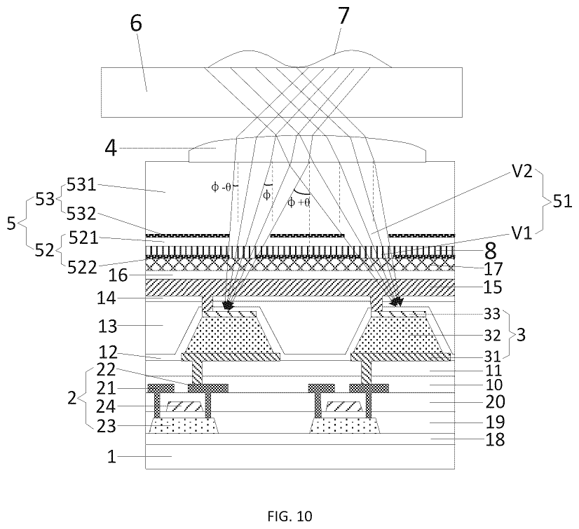

In some embodiments, in order to further filter out external ambient light and improve the fingerprint recognition performance, in the above optical sensor provided in embodiments of the present disclosure, as shown in FIGS. 9 and 10, the optical sensor further includes a light filter film layer 8. The light filter film layer 8 can be multiplexed as a transparent layer of any one of the diaphragm layers (52 and/or 53). For example, as shown in FIG. 9, the light filter film layer 8 is multiplexed as the transparent layer 521 of the diaphragm layer 52; and when setting, it can be selected according to different devices or application scenarios, which is not limited in the present disclosure. Or, the light filter film layer 8 is arranged inside the transparent layer (521 and/or 531) of any one of the diaphragm layers (52 and/or 53), and an orthographic projection of the light filter film layer 8 on the base substrate 1 at least covers orthographic projections of the openings (such as the light exiting holes V1) on the base substrate 1. For example, as shown in FIG. 10, the light filter film layer 8 is arranged inside the transparent layer 521 of the diaphragm layer 52; and when setting, it can be selected according to different devices or application scenarios, which is not limited in the present disclosure.

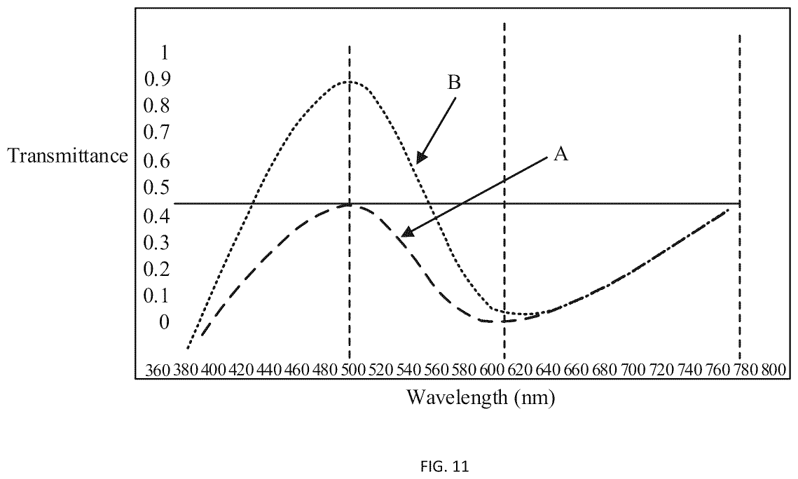

As shown in FIG. 11, which is the transmittance spectrum diagram of the light filter film layer in the visible light range, the curve A is the transmittance of the light filter film layer as shown in FIG. 9, and the curve B is the transmittance of the light filter film layer as shown in FIG. 10. The difference between the light filter film layers in FIG. 9 and FIG. 10 is that the thicknesses are different. Fingerprint recognition signals are generally between 380 nm and 600 nm, and their transmittance is defined as Ts. The value range of Ts is 10%˜50%, which can meet the fingerprint recognition requirements. The ambient light signals are generally between 600 nm and 780 nm, and their transmittance is defined as Ta. The value of Ta is less than 10%. It can be seen from FIG. 11 that the light filtering film layer provided by the embodiments of the present disclosure meets the requirements of fingerprint recognition performance and ambient light filtering.

In some embodiments, in the above optical sensor provided by embodiments of the present disclosure, as shown in FIGS. 5-7, 9 and 10, the light converged element 4 can be a lens, and the lens can be formed by a thermal reflow process. Because one lens provided by embodiments of the present disclosure covers four sub-pixels, the size of the lens is relatively large and easy to manufacture.

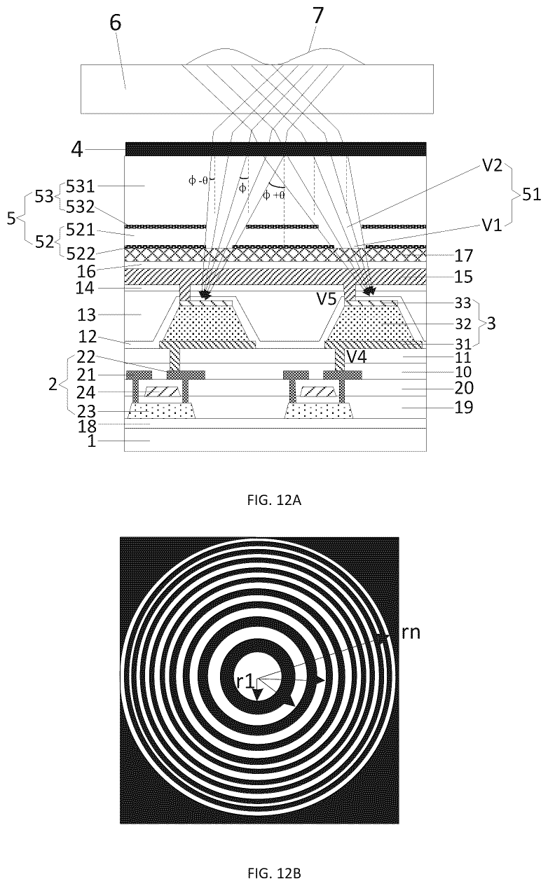

In some embodiments, in the above optical sensor provided by embodiments of the present disclosure, as shown in FIG. 12A, the light converged element 4 can be a Fresnel zone plate (FZP). Specifically, the Fresnel zone plate layout can be made of black resin through photolithography to realize the function of collimation and light gathering. As shown in FIG. 12B, the focal length of the Fresnel zone plate is f=(r1)\hat{ }2/λ, where λ is the wavelength; and rn=r1*(n)\hat{ }(0.5), n is the number of wave zones (each circle of black shading area), the value of n can be 1, 2, 3, . . . , and the value of n is related to the size of the corresponding photosensitive device 3. The aperture of the whole FZP is D=2rn. One FZP corresponds to four or more sub pixels. When one FZP corresponds to four sub pixels, D=2rn=2*P, and P is the size of the sub pixel.

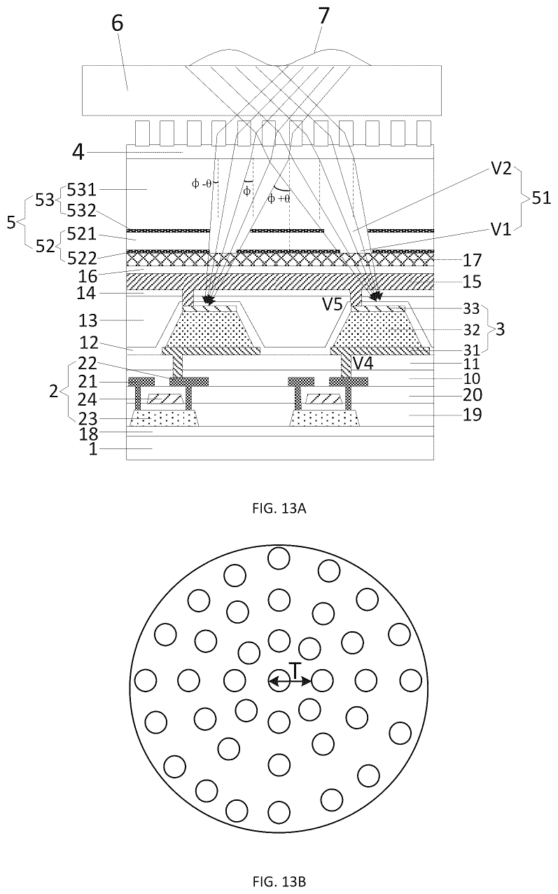

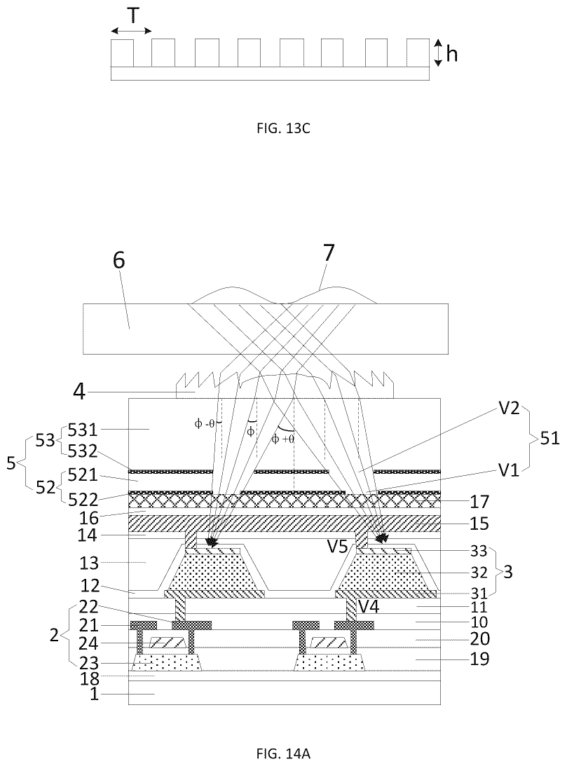

In some embodiments, in the above optical sensor provided by embodiments of the present disclosure, as shown in FIG. 13A, the light converged element 4 can be a grating. Specifically, the grating can modulate the light, so that the light reflected from the fingerprint is nearly collimated and incident on the photosensitive device, realizing the function of collimation and light gathering. As shown in FIG. 13B and FIG. 13C, FIG. 13B is the planar schematic diagram of a grating, and FIG. 13C is the cross-section schematic diagram of a grating. The grating period is T=500 nm, the duty cycle of the grating is 50%(radio of the light shielding area and the light transmission area is 1:1), and the groove depth h of the grating ranges from 0.1 μm to 1 μm. One grating corresponds to four or more sub pixels. Specifically, a layer of SiNx can be deposited by using the plasma enhanced chemical vapor deposition (PECVD) process, and a grating structure can be formed by etching on SiNx using a dry etching process.

In some embodiments, in the above optical sensor provided by embodiments of the present disclosure, as shown in FIG. 14A, the light converged element 4 can be a Fresnel lens. Specifically, the Fresnel lens can be made by using the embossing process, as shown in FIG. 14B, which is the planar schematic diagram of the Fresnel lens. On the basis of realizing the function of lens focusing, the Fresnel lens can save materials and reduce production costs.

It should be noted that FIG. 12A, FIG. 13A and FIG. 14A are diagrams that respectively replace the lens with the Fresnel zone plate, grating and Fresnel lens on the basis of the structure shown in FIG. 5. Of course, it can also replace the lens with the Fresnel zone plate, grating and Fresnel lens on the basis of the structure shown in FIG. 6 or FIG. 7.

In some embodiments, in the above optical sensor provided by embodiments of the present disclosure, as shown in FIG. 15A, the optical sensor also includes a light converged layer 4′ arranged on a side of the light constrained structure 5 facing away from the base substrate 1, the light converged layer 4′ includes a plurality of through-holes, and the through-hole 41′ constitutes the light converged element 4, that is, the through-hole 41′ realizes the function of collimation and light gathering. As shown in FIG. 15B, which is a planar schematic diagram of partial film layers in FIG. 15A, one light converged element 4 corresponds to four photosensitive devices 3 (sub pixels P). Specifically, the material of the light converged layer 4′ is the same as that of the light shielding layer (such as 522, 532).

It should be noted that FIG. 15A is a diagram that replaces the lens with the light converged layer 4′ on the basis of the structure shown in FIG. 5. Of course, it can also replace the lens with the light converged layer 4′ on the basis of the structure shown in FIG. 6 or FIG. 7.

In some embodiments, the above optical sensor provided by embodiments of the present disclosure, as shown in FIGS. 5-7, 9, 10, 12A, 13A, 14A and 15A, the optical sensor further includes: a first planarization layer 10 arranged between the detection circuit 2 and the photosensitive device 3, and a first passivation layer 11 arranged between the first planarization layer 10 and the photosensitive device 3. The photosensitive device 3 includes a bottom electrode 31, a photosensitive layer 32 (photosensitive PIN) and a top electrode 33 arranged in stacked on the first passivation layer 11; the bottom electrode 31 is electrically connected with the detection circuit 2 by a first via-hole V4 penetrating through the first passivation layer 11 and the first planarization layer 10; and an orthographic projection of the photosensitive layer 32 on the base substrate 1 does not overlap with an orthographic projection of the first via-hole V4 on the base substrate 1. In this way, the photosensitive layer 32 (photosensitive PIN) can avoid the area of the first via-hole V4, that is, the PIN is arranged in an irregular structure in the sub pixels (as reflected in the layout diagram later), which can ensure the flatness of the photosensitive layer 32 and reduce the noise caused by dark current.

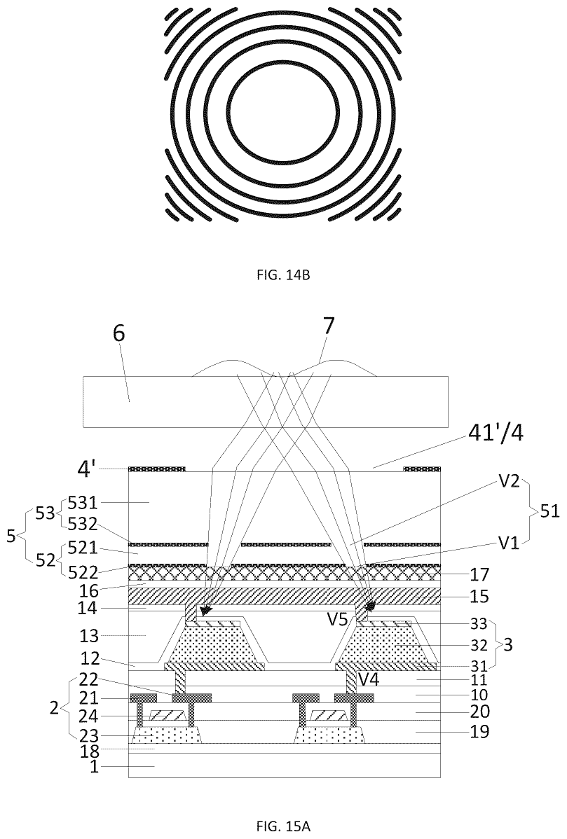

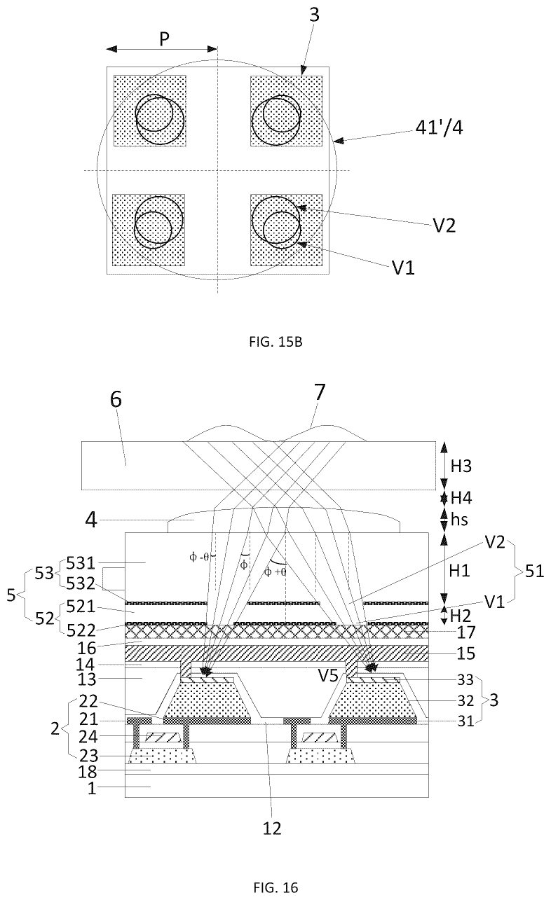

In some embodiments, in the above optical sensor provided by embodiments of the present disclosure, as shown in FIG. 16, the photosensitive device 3 includes a bottom electrode 31, a photosensitive layer 32 and a top electrode 33 arranged in stacked; the bottom electrode 31 is arranged in the same layer as source and drain electrodes (source electrode 21 and drain electrode 22) of the detection circuit 2; and the bottom electrode 31 and the drain electrode 22 of the detection circuit 2 are an integrated structure. In this way, when fabricating the source electrode and drain electrode of the detection circuit 2, the bottom electrode 31 of the photosensitive device 3 can be directly fabricated in the source and drain layer, which can save a separate mask for fabricating the bottom electrode 31 and save mass production costs.

Optionally, the material of the bottom electrode 31 may be a metal material, and the material of the top electrode 33 may be a transparent conductive material.

It should be noted that in FIG. 16, the bottom electrode 31 is arranged in the same layer as the source and drain electrodes (source electrode 21 and drain electrode 22) of the detection circuit 2 on the basis of the structure shown in FIG. 5. Of course, the bottom electrode 31 may also be arranged in the same layer as the source and drain electrodes (source electrode 21 and drain electrode 22) of the detection circuit 2 on the basis of the structure shown in FIG. 6 or FIG. 7.

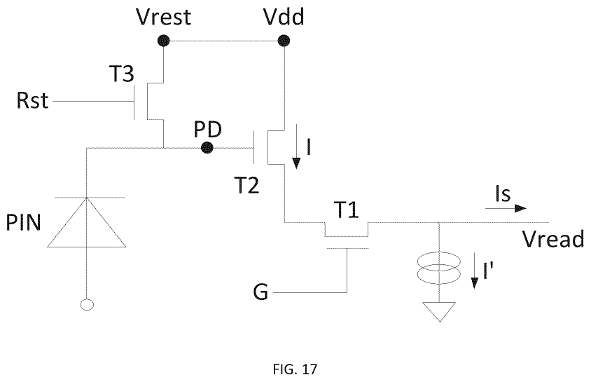

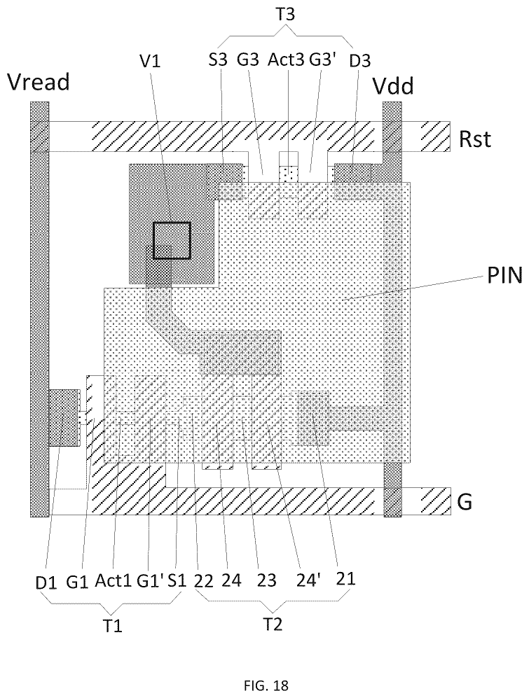

In some embodiments, in the above optical sensor provided by embodiments of the present disclosure, as shown in FIG. 5 to FIG. 7, FIG. 9, FIG. 10, FIG. 12A, FIG. 13A, FIG. 14A, FIG. 15A, FIG. 16, FIG. 17 and FIG. 18, FIG. 17 is schematic diagram of an equivalent circuit of the detection circuit, and FIG. 18 is a layout diagram of the detection circuit. The detection circuit includes a first transistor T1, a second transistor T2 and a third transistor T3; a gate electrode of the first transistor T1 is electrically connected with a first control line G, a first electrode of the first transistor T1 is electrically connected with a signal reading end Vread, and a second electrode of the first transistor T1 is electrically connected with a first electrode of the second transistor T2; a second electrode of the second transistor T2 is electrically connected with a first power supply terminal Vdd, and a gate electrode of the second transistor T2 and a first electrode of the third transistor T3 are both electrically connected with the photosensitive device 3; and a second electrode of the third transistor T3 is electrically connected with a reset signal line Vrest, and a gate electrode of the third transistor T3 is electrically connected with a second control line Rst. The first transistor T1, the second transistor T2 and the third transistor T3 are all double-gate structures, which can reduce the leakage current and improve the stability of the first transistor T1, the second transistor T2 and the third transistor T3.

Specifically, as shown in FIG. 17, the second transistor T2 is used to convert the charge change in the photosensitive device 3 (PIN) into the current change; when the third transistor T3 is turned on, a potential of the PD point is reset to the reset voltage (Vreset) to achieve the reset of the photosensitive device 3 (PIN); when the third transistor T3 is turned off, it starts to enter the signal reading stage, and the potential of the PD point decreases due to the accumulation of photo-charges; and the first transistor T1 controls the signal output and reads the fingerprint recognition signal; where, Vrest can share the same signal trace with Vdd to reduce the noise interference caused by increased traces. As shown in FIG. 18, in order to ensure the flatness of the PIN and reduce the noise caused by dark current, the PIN avoids the area of the first via-hole V4 of the first planarization layer 10 and the first passivation layer 11 in FIG. 5 to FIG. 7, FIG. 9, FIG. 10, FIG. 12A, FIG. 13A, FIG. 14A and FIG. 15A. The second transistor T2 converts the charge change into current change. According to the formula I=½ u*C_ox*(V_GS−Vth)\hat{ }2, the current I′ flowing through the base constant current source is fixed, and the value of the read signal is Is=I-I′. Under the condition of a constant voltage change at the PD point, it can be obtained from the formula that the signal value is mainly related to u (mobility) and C_ox (TFT capacitance characteristics). Here, the second transistor T2 takes a larger width-to-length ratio W/L, for example, W/L is taken as 5/(3.5+3.5) for double-gate design. The first transistor controls signal output and cuts off interference between rows. It is required that I_off (off state current) be as small as possible to prevent Is from mixing with other row of leakage currents during signal conversion, so the smaller W/L is taken here, for example, 2/(3.5+3.5) for double-gate design is taken. The third transistor T3 resets the potential of the PD point to Vreset, achieving the reset of the photosensitive device (PIN). It is required that I_off be as small as possible to prevent leakage from Vreset to the PD point during the exposure phase. I_on (on state current) of the third transistor T3 should be as large as possible to improve the reset speed of the Pd point and reduce the required reset time. Therefore, a width-to-length ratio of the third transistor T3 can be greater than or equal to a width-to-length ratio of the first transistor T1, such as 5/(3.5+3.5) for double-gate design. Therefore, in the above optical sensor provided by embodiments of the present disclosure, the width-to-length ratio of the second transistor T2 is greater than the width-to-length ratio of the third transistor T3, and the width-to-length ratio of the third transistor T3 is greater than or equal to the width-to-length ratio of the first transistor T1.

Specifically, the first transistor T1, the second transistor T2 and the third transistor T3 can be the top gate structures or the bottom gate structures, which is not limited in the present disclosure. In embodiments of the present disclosure, the top gate structure is used as an example for illustration, and in application, the selection can be made according to different devices or application scenarios.

As shown in FIG. 18, the first transistor T1 includes an active layer Act1, a source electrode S1, a drain electrode D1, and gate electrodes G1 and G11; the second transistor T2 includes an active layer 23, a source electrode 21, a drain electrode 22, and gate electrodes 24 and 24′; and the third transistor T3 includes an active layer Act3, a source electrode S3, a drain electrode D3, and gate electrodes G3 and G3′.

In some embodiments, in the above optical sensor provided by embodiments of the present disclosure, as shown in FIG. 5 to FIG. 7, FIG. 9, FIG. 10, FIG. 12A, FIG. 13A, FIG. 14A, FIG. 15A and FIG. 16, the optical sensor further includes: a cover layer 12 arranged between the photosensitive devices 3 and the light constrained structure 5; a second planarization layer 13 arranged between the cover layer 12 and the light constrained structure 5; a second passivation layer 14 arranged between the second planarization layer 13 and the light constrained structure 5; a first transparent electrode layer 15 arranged between the second passivation layer 14 and the light constrained structure 5; a barrier layer 16 arranged between the first transparent electrode layer 15 and the light constrained structure 5; and a second transparent electrode layer 17 arranged between the barrier layer 16 and the light constrained structure 5. Here, the first transparent electrode layer 15 is electrically connected with the top electrode 33 of the photosensitive device 3 by a second via-hole V5 penetrating through the second passivation layer 14, the second planarization layer 13 and the cover layer 12.

Specifically, the first transparent electrode layer 15 is used as the lead of the top electrode 33 to realize the electrical connection between the top electrode 33 and the bias voltage. The second transparent electrode layer 17 can be used as a shielding layer to cover the entire display panel 6, which can prevent the parasitic capacitance from affecting the photosensitive device (PIN).

In some embodiments, in the above optical sensor provided by embodiments of the present disclosure, as shown in FIGS. 5 to 7, 9, 10, 12A, 13A, 14A and 15A, the detection circuit 2 further includes an active layer 23 and a gate electrode 24; and the optical sensor further includes: a buffer layer 18 between the base substrate 1 and the detection circuit 2, a gate insulation layer 19 between the active layer 23 and the gate electrode 24, and the interlayer insulation layer 20 between the gate electrode 24 and the source and drain electrodes (21 and 22).

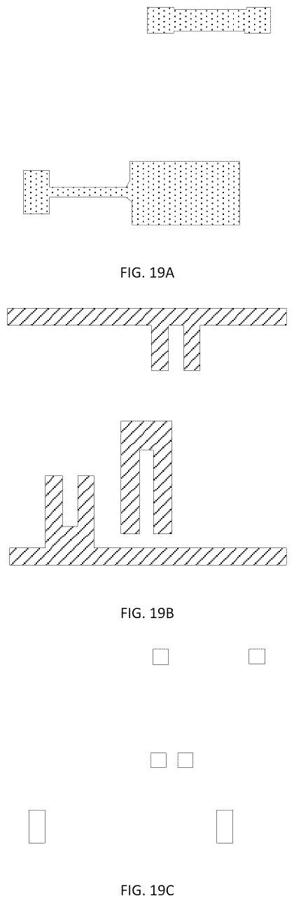

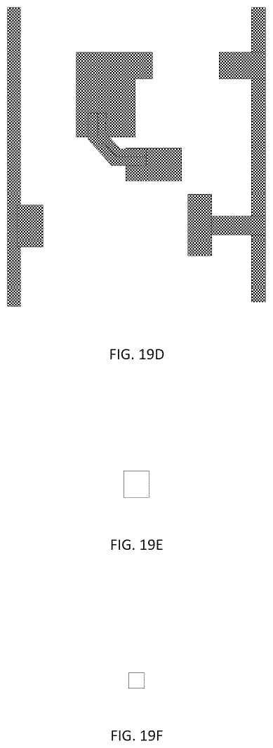

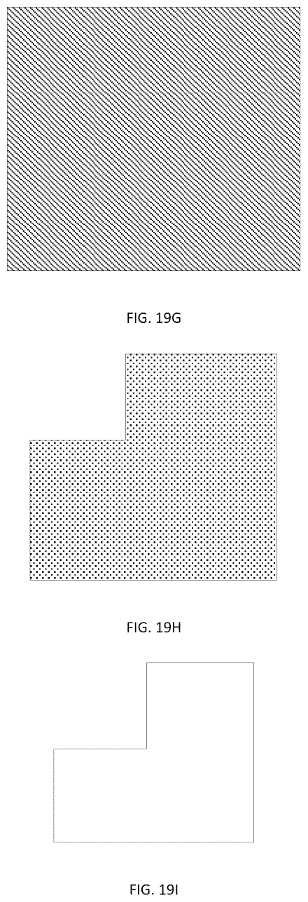

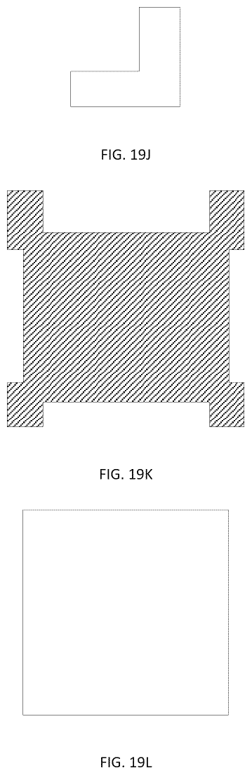

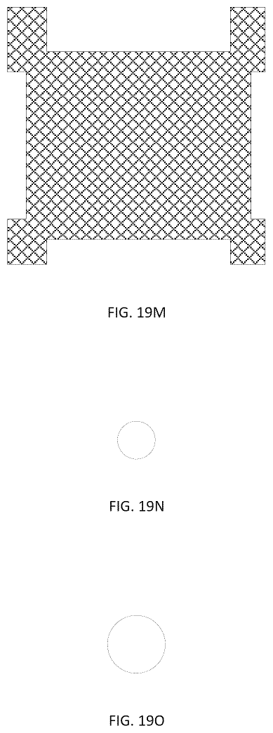

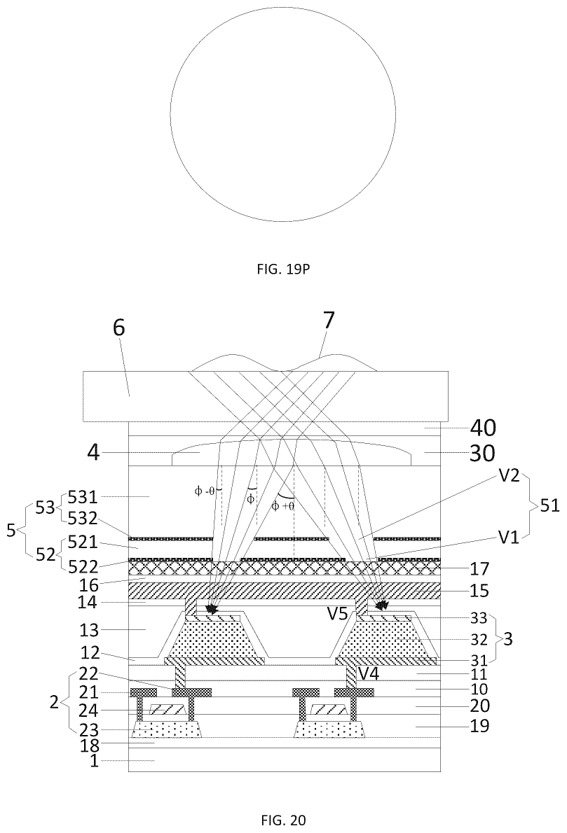

Taking the structure shown in FIG. 5 as an example, the layout diagrams of the main film layers are shown below, as shown in FIG. 19A to FIG. 19P. FIG. 19A is a planar schematic diagram of the active layer 23; FIG. 19B is a planar schematic diagram of the gate electrode 24; FIG. 19C is a planar schematic diagram of the interlayer insulation layer 20 (only holes are shown); FIG. 19D is a planar schematic diagram of the source and drain electrodes (21 and 22); FIG. 19E is a planar schematic diagram of the first planarization layer 10; FIG. 19F is a planar schematic diagram of the first passivation layer 11; FIG. 19G is a planar schematic diagram of the bottom electrode 31; FIG. 19H is a planar schematic diagram of the photosensitive layer 32; FIG. 19I is a planar schematic diagram of the second planarization layer 13; FIG. 19J is a planar schematic diagram of the second passivation layer 14; FIG. 19K is a planar schematic diagram of the first transparent electrode layer 15; FIG. 19L is a planar schematic diagram of the barrier layer 16; FIG. 19M is a planar schematic diagram of the second transparent electrode layer 17; FIG. 19N is a planar schematic diagram of the light exiting hole V1; FIG. 19O is a planar schematic diagram of the light incident hole V2; and FIG. 19P is a planar schematic diagram of the light converged element 4.

In embodiments of the present disclosure, taking the structure shown in FIG. 5 as an example, in order to achieve the configuration of optical channel 51 to allow incident light with an angle within the range of (ϕ−θ, ϕ+θ) to be directed onto the photosensitive device 3 and also to block ambient light, the parameters need to satisfy the following relationship.

As shown in FIG. 3 and FIG. 5, D=2P-t; where t is the distance between two adjacent light converged elements 4, D is the clear aperture of light converged element 4, and P is the size of photosensitive device 3 (sub pixel). The value of t ranges from 0.2 μm to 10 μm, the value of D ranges from 1.8 μm to 190 μm, and the value of P ranges from 1 μm to 100 μm.

As shown in FIG. 3 and FIG. 5, H1+H2=(D\hat{ }2+4hs\hat{ }2)*(nt/(ns−1))−nt*hs/ns; where nt is the refractive index of the transparent layers (521 and 531), ns is the refractive index of the light converged element 4, hs is the arch height of the light converged element 4, and H1 and H2 are the thicknesses of transparent layers (531 and 521) respectively. The value of nt ranges from 1.4 to 1.6, the value of ns ranges from 1.65 to 2.1, and the value of hs ranges from 0.5 μm to 20 μm.

As shown in FIG. 3 and FIG. 5, d1=(D\hat{ }2+4hs\hat{ }2)*(nt/(ns−1))*(cot(ϕ+θ)− cot(ϕ−θ)); where d1 is the size of the opening (the light exiting hole V1) of the light shielding layer 522 close to the photosensitive device 3. The value of d1 ranges from 0.2 μm to 7.3 m.

As shown in FIG. 3 and FIG. 5, d2=H2*D/((D\hat{ }2+4hs\hat{ }2)*(nt/(ns−1))−nt*hs/ns); where d2 is the size of the opening (the light incident hole V2) of the light shielding layer 532 far away from the photosensitive device 3.

As shown in FIG. 3 and FIG. 5, d1y=H1+H2, and d1x=d1y*tan ϕ; where d1y is an offset in a direction Y of a center of the opening in the light shielding layer 522 close to the photosensitive device 3 relative to a center of the light converged element 4, and d1x is an offset in a direction X of the center of the opening in the light shielding layer 522 close to the photosensitive device 3 relative to the center of the light converged element 4. The value of d1y ranges from 2 μm to 40 μm.

As shown in FIG. 3 and FIG. 5, d2y=H1, and d2x=d2y*tan ϕ; where d2y is an offset in the direction Y of a center of the opening in the light shielding layer 532 far away from the photosensitive device 3 relative to the center of the light converged element 4, and d2x is an offset in the direction X of the center of the opening in the light shielding layer 532 far away from the photosensitive device 3 relative to the center of the light converged element 4. The value of d2y ranges from 1 μm to 20 μm.

Specifically, as shown in FIG. 3 and FIG. 5, due to the need for oblique light rays to pass through the light incident hole V2 and the light exiting hole V1 spatially, it is necessary to ensure that the coordinates of the light incident hole V2 and the light exiting hole V1 cannot be the same. As the light exiting hole V1 is located below the light incident hole V2, d2x<d1x, and d2y<d1y.

Specifically, as shown in FIG. 5, the overall thickness H3 of the display panel 6 can range from 0.1 mm to 1.4 mm, and the distance H4 between the upper surface of the optical sensor (the upper surface of the light converged element 4) and the lower surface of the display panel 6 can range from 100 μm to 600 μm.

Based on the same inventive concept, an embodiment of the present disclosure also provides a display apparatus, as shown in FIG. 20, and the display apparatus includes a display panel 6 and the optical sensor provided by embodiments of the present disclosure and arranged on the back surface of the display panel 6. The display apparatus can be a mobile phone, a tablet computer, a television, a monitor, a notebook computer, a digital photo frame, a navigator and other products or components with display functions. The implementation of the display apparatus may refer to the above-mentioned embodiments of the optical sensor, and the repetition will not be described here.

Specifically, the display panel 6 includes a glass cover plate, an optical adhesive layer (OCA, optically clear adhesive), a polarizer, a thin film encapsulation (TFE) layer, a cathode, an electroluminescence (EL) layer, an anode, a drive backplane and other film layers which are stacked in sequence.

In some embodiments, the above display apparatus provided by embodiments of the present disclosure, as shown in FIG. 20, further includes: the third planarization layer 30 between the light converged element 4 and the display panel 6, and the optical adhesive layer 40 (OCA) between the third planarization layer 30 and the display panel 6. Specifically, a third planarization layer 30 is manufactured after the manufacturing process of the light converged element 4, which plays the role of flattening and can protect the light converged element 4 from wear and tear. Then the entire module of the optical sensor is bonded to the display panel 6 by an optical adhesive layer 40 (OCA). The advantage of setting the third planarization layer 30 compared to having an air gap between the display panel 6 and the module of the optical sensor is that the present disclosure prevents inaccurate fingerprint recognition caused by different pressing forces.

Optionally, the refractive index of the third planarization layer 30 ranges from 1.0 to 1.5. The material of the third planarization layer 30 can be OC, poly (acrylic acid 1,1,1,3,3,3-hexafluoroisopropyl ester), poly (2,2,3,3,4,4,4-heptafluorobutyl acrylate), poly (2,2,3,3,4,4,4-heptafluorobutyl methacrylate), poly (2,2,3,3,3-pentafluoropropylacrylate), poly (1,1,1,3,3,3-hexafluoroisopropyl methacrylate), poly (2,2,3,4,4,4-hexafluorobutyl acrylate), poly (2,2,3,4,4,4-hexafluorobutyl methacrylate), poly (2,2,3,3,3-pentafluoropropyl methacrylate).

Embodiments of the disclosure provide an optical sensor and a display apparatus. During fingerprint recognition, when the finger touches the screen of display panel, the optical channels can filter out the light reflected from the fingerprint of the finger with the small angle (ϕ−θ, ϕ+θ), which is nearly collimated, allowing it reach the photosensitive devices below. The photosensitive devices can detect the intensity of the light. The energy of the downward diffuse reflection light from the valley and ridge of the fingerprint is different, and the light intensity detected by the photosensitive device array is different, so that the fingerprint information can be obtained and achieve large-scale fingerprint recognition. In addition, by arranging the oblique optical channels, and by adjusting the design of the optimal matching relationship between the parameters in the light constrained structure and the size and position of the photosensitive devices below, the light constrained structure can control its light receiving angle within the range of (ϕ−θ, ϕ+θ), allow only part of the light to enter the photosensitive devices, and block the light within a certain angle range, to solve the problem of the impact of external strong ambient light on the optical sensing performance, and further improve the recognition performance. In addition, by setting a light converged element to cover at least two photosensitive devices, that is, the size of the light converged element is larger than the size of the photosensitive device, it is possible to make a large-sized light converged element, reducing the process difficulty. Moreover, when the photosensitive devices are made in a large area array, since two adjacent optical channels are symmetrically arranged about the central axis of the light converged element, the two adjacent light constrained structures can image the fingerprint twice. On the one hand, the collected images can complement each other to improve the accuracy of fingerprint recognition, and on the other hand, the number of photosensitive devices can be reduced on the basis of achieving the same resolution, while also reducing the space occupied by optical sensors in the electronic device. Therefore, embodiments of the present disclosure can realize the fingerprint collimation scheme design by using multiple photosensitive devices to share the same light converged element without reducing the resolution.

Although the preferred embodiments of the present disclosure have been described, those skilled in the art will be able to make additional changes and modifications to these embodiments once the basic inventive concepts are obtained. Therefore, it is intended that the appended claims be construed to include the preferred embodiments and all changes and modifications that fall within the scope of the disclosure.

Evidently, those skilled in the art can make various modifications and variations to the present disclosure without departing from the spirit and scope of the present disclosure. Thus the present disclosure is also intended to encompass these modifications and variations therein as long as these modifications and variations to the present disclosure come into the scope of the claims of the present disclosure and their equivalents.

What is claimed is:

1. An optical sensor, comprising:
a base substrate;
a detection circuit on the base substrate;
a plurality of photosensitive devices on a side of the detection circuit facing away from the base substrate;
a plurality of light converged elements on a side of the plurality of photosensitive devices facing away from the base substrate; wherein an orthographic projection of one of the plurality of light converged elements on the base substrate covers orthographic projections of at least two of the plurality of photosensitive devices on the base substrate; and
a light constrained structure between the plurality of photosensitive devices and the plurality of light converged elements; wherein the light constrained structure comprises a plurality of optical channels corresponding to the plurality of photosensitive devices one by one; each of the plurality of optical channels is obliquely arranged, and adjacent two optical channels are symmetrically arranged about a central axis of one light converged element; and each of the plurality of optical channels is configured to allow incident light within an incidence angle of (ϕ−θ, ϕ+θ) to be directed onto the photosensitive device, wherein, ¢ is an angle between a central axis of the optical channel and the central axis of the light converged element.

2. The optical sensor according to claim 1, wherein the orthographic projection of the light converged element on the base substrate covers orthographic projections of k² photosensitive devices on the base substrate;
wherein k is a positive even number.

3. The optical sensor according to claim 1, wherein a value of ϕ ranges from 42° to 70°; and a value of 0 ranges from 0.5° to 12°.

4. The optical sensor according to claim 1, wherein the light constrained structure comprises at least two diaphragm layers arranged in stacked;
each of the at least two diaphragm layers has a plurality of openings which are in one-to-one correspondence with the plurality of photosensitive devices; and
at least two stacked openings above each of the plurality of photosensitive devices are arranged in a staggered manner to form an optical channel corresponding to the photosensitive device.

5. The optical sensor according to claim 1, wherein the light constrained structure comprises at least two diaphragm layers arranged in stacked;
the diaphragm layer closest to the plurality of light converged elements has a plurality of first openings;
the diaphragm layer close to the plurality of photosensitive devices has a plurality of second openings which are in one-to-one correspondence with the plurality of photosensitive devices;
an orthographic projection of one of the plurality of first openings on the base substrate covers orthographic projections of at least two of the plurality of second openings on the base substrate;
a connecting line between a center point of the first opening and a center point of the second opening is obliquely arranged; and
the first opening and the second opening stacked above each of the plurality of photosensitive devices form the optical channel.

6. The optical sensor according to claim 5, wherein the orthographic projection of the first opening on the base substrate covers orthographic projections of k² second openings on the base substrate, wherein k is a positive even number.

7. The optical sensor according to claim 4, wherein each of the at least two diaphragm layers comprises a transparent layer and a light shielding layer on a surface of the transparent layer facing away from the light converged element, and the light shielding layer is provided with the plurality of openings.

8. The optical sensor according to claim 7, further comprising a light filter film layer; wherein:
the light filter film layer is multiplexed as the transparent layer of any one of the diaphragm layers; or
the light filter film layer is inside the transparent layer of any one of the diaphragm layers, and an orthographic projection of the light filter film layer on the base substrate at least covers an orthographic projection of the opening on the base substrate.

9. The optical sensor according to claim 7, wherein a shape of the opening is a triangle, a square or a circle.

10. The optical sensor according to claim 7, wherein the optical sensor satisfies a following relationship:
D=2P−t; wherein, t is a distance between two adjacent light converged elements, D is a clear aperture of the light converged element, and P is a size of the photosensitive device;
H1+H2=(D\hat{ }2+4hs\hat{ }2)*(nt/(ns−1))−nt*hs/ns; wherein, nt is a refractive index of the transparent layer, ns is a refractive index of the light converged element, hs is an arch height of the light converged element, and H1 and H2 are thicknesses of transparent layers respectively;
d1=(D\hat{ }2+4hs\hat{ }2)*(nt/(ns−1))*(cot(ϕ+θ)− cot(ϕ−θ)); wherein d1 is a size of an opening of the light shielding layer close to the photosensitive device;
d2=H2*D/((D\hat{ }2+4hs\hat{ }2)*(nt/(ns−1))−nt*hs/ns); wherein d2 is a size of an opening of the light shielding layer far away from the photosensitive device;
d1y=H1+H2, and d1x=d1y*tan ϕ; wherein, d1y is an offset in a direction Y of a center of the opening in the light shielding layer close to the photosensitive device relative to a center of the light converged element, and d1x is an offset in a direction X of the center of the opening in the light shielding layer close to the photosensitive device relative to the center of the light converged element; and
d2y=H1, and d2x=d2y*tan ϕ; wherein, d2y is an offset in the direction Y of a center of the opening in the light shielding layer far away from the photosensitive device relative to the center of the light converged element, and d2x is an offset in the direction X of the center of the opening in the light shielding layer far away from the photosensitive device relative to the center of the light converged element.

11. The optical sensing according to claim 1, wherein the light converged element comprises at least one of: a lens, a Fresnel zone plate, a grating, or a Fresnel lens.

12. The optical sensor according to claim 1, further comprising a light converged layer on a side of the light constrained structure facing away from the base substrate;
wherein the light converged layer comprises a plurality of through-holes, and the through-hole constitutes the light converged element.

13. The optical sensor according to claim 1, further comprising: a first planarization layer between the detection circuit and the photosensitive device, and a first passivation layer between the first planarization layer and the photosensitive device;
wherein the photosensitive device comprises a bottom electrode, a photosensitive layer and a top electrode arranged in stacked on the first passivation layer; the bottom electrode is electrically connected with the detection circuit by a first via-hole penetrating through the first passivation layer and the first planarization layer; and an orthographic projection of the photosensitive layer on the base substrate does not overlap with an orthographic projection of the first via-hole on the base substrate.

14. The optical sensor according to claim 1, wherein the photosensitive device comprises a bottom electrode, a photosensitive layer and a top electrode arranged in stacked;
wherein the bottom electrode is arranged in a same layer as source and drain electrodes of the detection circuit, and the bottom electrode and the drain electrode of the detection circuit are an integrated structure.

15. The optical sensor according to claim 13, wherein the detection circuit comprises a first transistor, a second transistor and a third transistor;
a gate electrode of the first transistor is electrically connected with a first control line, a first electrode of the first transistor is electrically connected with a signal reading end, and a second electrode of the first transistor is electrically connected with a first electrode of the second transistor;
a second electrode of the second transistor is electrically connected with a first power supply terminal, and a gate electrode of the second transistor and a first electrode of the third transistor are both electrically connected with the photosensitive device; and
a second electrode of the third transistor is electrically connected with a reset signal line, and a gate electrode of the third transistor is electrically connected with a second control line;
wherein the first transistor, the second transistor and the third transistor are all double-gate structures.

16. The optical sensor according to claim 15, wherein a width-to-length ratio of the second transistor is greater than a width-to-length ratio of the third transistor, and the width-to-length ratio of the third transistor is greater than or equal to a width-to-length ratio of the first transistor.

17. The optical sensor according to claim 1, further comprising:
a cover layer between the photosensitive device and the light constrained structure;
a second planarization layer between the cover layer and the light constrained structure;
a second passivation layer between the second planarization layer and the light constrained structure;
a first transparent electrode layer between the second passivation layer and the light constrained structure;
a barrier layer between the first transparent electrode layer and the light constrained structure; and
a second transparent electrode layer between the barrier layer and the light constrained structure;
wherein the first transparent electrode layer is electrically connected with the top electrode of the photosensitive device by a second via-hole penetrating through the second passivation layer, the second planarization layer and the cover layer.

18. A display apparatus, comprising a display panel and the optical sensor according to claim 1;
wherein the optical sensor is arranged on a back surface of the display panel.

19. The display apparatus according to claim 18, further comprising:
a third planarization layer between the light converged element and the display panel; and
an optical adhesive layer between the third planarization layer and the display panel.
